(19) United States
(12) Patent Application Publication
(10) Pub. No.: US 2007/0247819 A1
(43) Pub. Date: Oct. 25, 2007

(54) MEMORY MODULE ASSEMBLY INCLUDING HEAT DISSIPATING MEMBERS

(75) Inventors: CHUN-CHI CHEN, TU CHENG (TW); SHIH-HSUN WUNG, TU CHENG (TW); GUANG YU, Shenzhen (CN); DA-YUAN ZHOU, Shenzhen (CN); JIN-BIAO LIU, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., TU CHENG (TW)

(21) Appl. No.: 11/308,701

(22) Filed: Apr. 24, 2006

(51) Int. Cl. H05K 7/00

(52) U.S. Cl. 361/729

(57) ABSTRACT

A memory module assembly includes a memory card having a circuit board and a plurality of electronic components mounted on the circuit board. A pair of shells covers two faces of the memory card for dissipating heat generated by the electronic components of the memory card. A pair of clips each clamps the pair of shells and memory card. Each of the pair of clips has a pair of abutting pieces being pivotably connected together and resilient pressing the pair of shells toward the electronic components of the memory card. The abutting pieces of the pair of clips are detachably engaged with the pair of shells, and form protrusions thereon engaging in indentations defined in the shells.

### FIELD OF THE INVENTION

The present invention relates generally to a memory module assembly, and more particularly to a memory module assembly including heat dissipating members for dissipating heat generated by electronic components of the memory module.

### DESCRIPTION OF RELATED ART

Memory module assemblies that are currently in use generally do not require cooling devices to dissipate heat. The electronic components and memory module assemblies, which are operated at or below 66 MHz, do not generate a large amount of heat that requires a cooling device for dissipating the heat. However, as the industry progresses, memory module assemblies such SDRAM DIMM memory module assemblies are required to be operated at 100 MHz and above. For these state-of-the-art memory module assemblies, heat dissipating members will be required to remove heat generated thereby. Therefore, a locking device such as a clip is desired in order to secure the heat dissipating members to these state-of-the-art memory module assemblies.

What is needed, therefore, is a memory module assembly incorporating a heat dissipating member with great heat dissipating capacity and a clip for easily mounting the heat dissipating member to the memory module assembly.

### SUMMARY OF INVENTION

A memory module assembly in accordance with a preferred embodiment of the present invention comprises a memory card having a circuit board and a plurality of electronic components mounted on the circuit board. A pair of shells sandwiches the memory card therebetween and covers two faces of the memory card, for dissipating heat generated by the electronic components of the memory card. A pair of clips each clamps the pair of shells and memory card and pushes the pair of shells toward the memory card. Each of the pair of clips has a pair of abutting pieces pivotably connected together and resiliently pressing the pair of shells toward the electronic components of the memory card. The abutting pieces of the pair of clips are detachably engaged with the pair of shells, and have protrusions formed thereon engaging in indentations defined in the shells.

Other advantages and novel features will become more apparent from the following detailed description of preferred embodiments when taken in conjunction with the accompanying drawings, in which:

### BRIEF DESCRIPTION OF DRAWINGS

FIG. 1 is an exploded, isometric view of a memory module assembly in accordance with a preferred embodiment of the present invention;

FIG. 2 shows an exploded view of a clip of FIG. 1;

FIG. 3 is an assembled view of FIG. 1;

FIG. 4 is an exploded, isometric view of a memory module assembly in accordance with an alternative embodiment of the present invention; and

FIG. 5 is an assembled view of FIG. 4.

### DETAILED DESCRIPTION

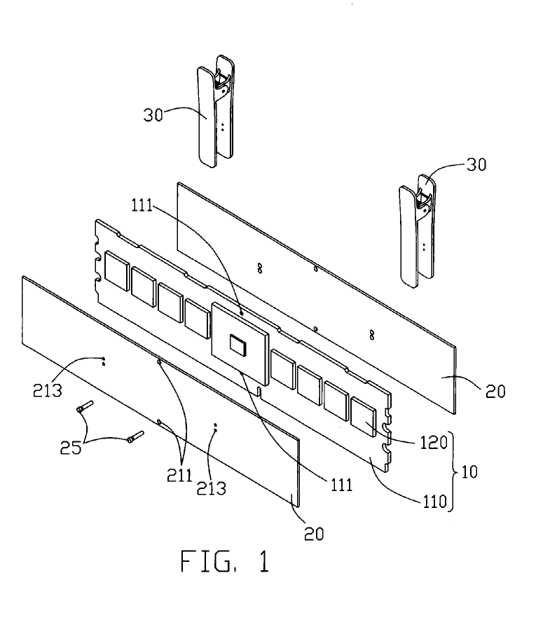

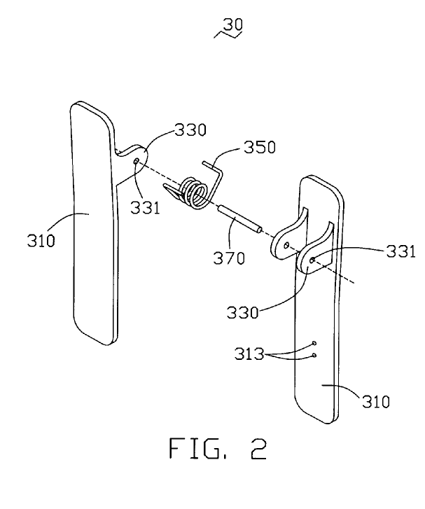

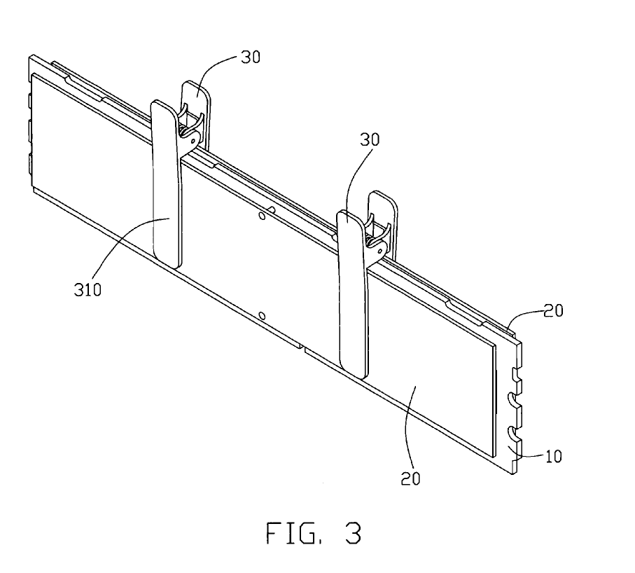

Referring to FIGS. 1-3, a memory module assembly in accordance with a preferred embodiment of the present invention comprises a memory card 10, a pair of heat dissipating shells 20 sandwiching the memory card 10 therebetween and covering two faces of the memory card 10, and a pair of clips 30 securing the shells 20 to the memory card 10.

The memory card 10 has a circuit board 110 and a plurality of electronic components 120 mounted on two faces thereof. Centers of the upper and low boundaries of the circuit board 110 respectively define two fixing apertures 111 therein.

Each shell 20 is manufactured from thermal conductive material such as a metal plate. Corresponding the fixing apertures 111 of the circuit board 110 of the memory card 10, two fixing holes 211 are defined in upper and low boundaries of each shell 20. Two fasteners 25 such as bolts are engaged in the fixing holes 211 and the fixing apertures 111, thereby fastening the pair of shells 20 and the memory card 10 together. Two pairs of locating indentions 213 are defined in an outer face of each of the pair of shells 20. The two pairs of locating indentions 213 are so located that the fixing holes 211 are located between the indentions 213. The locating indentions 213 of each of the two pairs of locating indentions 213 are vertically arranged on the shell 20.

Each clip 30 comprises a pair of lathes 310 pivotably connected together. The lathes 310 each extend a pair of spaced tabs 330 each defining a through aperture 331 therein adjacent to a free end thereof, wherein the tabs 330 of one lath 310 nip the tabs 330 of the other lath 310 therebetween. A torsion spring 350 has a spring coil (not labeled) which is sandwiched between the tabs 330 of the other lath 310, and two arms (not labeled) flipping from two ends of the spring coil and abutting against the lathes 310, respectively. A post 370 extends through the through apertures 331 of the tabs 330 and the spring coil of the spring 350 to connect the lathes 310 and the spring 350 together. The lathes 310 are pivotable about the post 370. Therefore, portions of the lathes 310 of the clip 30 below the post 370 can clamp an article therebetween with a spring force exerted by the spring 350.

In assembly, the pair of clips 30 each clamps the pair of shells 20 toward the memory card 10 via the lathes 310 thereof resiliently abutting against the outer faces of the pair of shells 20 toward the memory card 10. Corresponding to the locating indentions 213 of the shells 20, the lathes 310 of the clips 30 each extend a pair of protrusions 313 detachably engaged in corresponding locating indentions 213. Therefore, the shells 20 and the memory card 10 are assembled together with the shells 20 intimately contacting the electronic components 120 of the memory card 10. The protrusions 313 are vertically arranged on the lath 310. Although it is not shown in the drawings, it can be easily understood by persons skilled in the art that thermal medium such as a thermal tape is used to be sandwiched between the electronic components 120 and a corresponding shell 20 whereby the electronic components 120 and the shells 20 can have a good thermal connection.

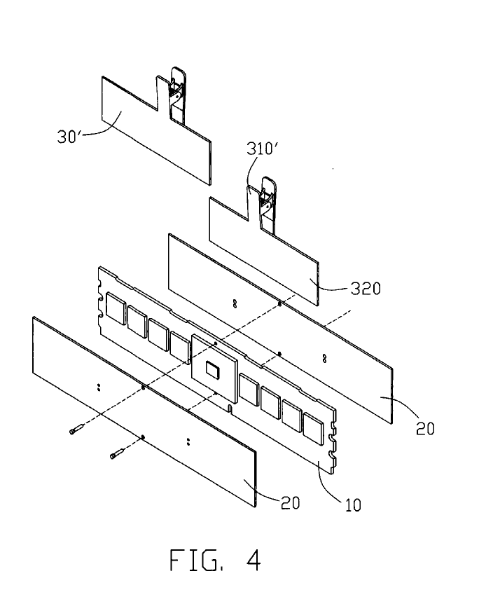

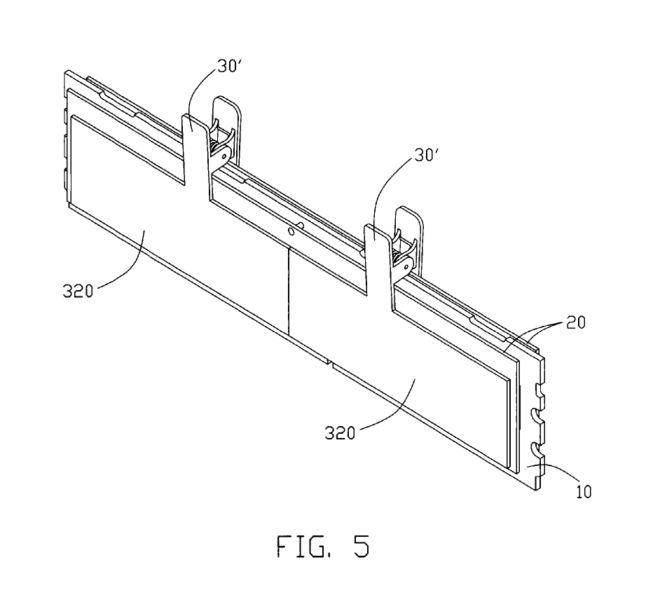

Referring to FIGS. 4 and 5, a memory module assembly in accordance with an alternative embodiment of the present invention is shown. The memory module assembly is similar to the previous preferred embodiment; the difference between the two embodiments is that the pair of clips 30′ in accordance with the second embodiment each has a lath 310′ with a lower portion thereof expanding laterally to form an elongated board 320 for abutting against an outer face of a corresponding shell 20.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A memory module assembly comprising:
a memory card having a circuit board and a plurality of electronic components mounted on the circuit board;
a pair of shells sandwiching the memory card therebetween, for thermally connecting with and dissipating heat generated by the electronic components of the memory card; and a pair of clips each having two lathes clamping the memory card and the pair of shells therebetween, the two lathes being pivotably connected together and resiliently pressing the pair of shells toward the electronic components of the memory card.

2. The memory module assembly of claim 1, wherein the pair of clips are detachably engaged with the pair of shells.

3. The memory module assembly of claim 2, wherein the lathes of the pair of clips have a plurality of protrusions engaged in a plurality of indentions defined in the pair of shells.

4. The memory module assembly of claim 1, wherein the pair of clips each has a torsion spring sandwiched between the lathes thereof.

5. The memory module assembly of claim 4, wherein the pair of lathes of each of the pair of clips extend two pairs of tabs through which a post extends to thereby pivotably connect the pair of lathes together.

6. The memory module assembly of claim 5, wherein each of the lathes of the pair of clips has a lower portion for pressing the pair of shells toward the memory card.

7. The memory module assembly of claim 6, wherein one of the lathes of each of the pair of clips has the lower portion thereof expanding laterally to form a board for contacting an outer face of one of the pair of shells.

8. The memory module assembly of claim 5, wherein each of the pair of clips has the spring located between the tabs thereof with the post extending through a spring coil of the spring.

9. The memory module assembly of claim 8, wherein the spring of each of the pair of clips extends two arms from two ends of the spring coil to abut the pair of lathes.

10. The memory module assembly of claim 1, wherein the pair of shells are fixed to the circuit board of the memory card via a plurality of fasteners extending through the shells and the circuit board of the memory card.

11. A memory module assembly comprising:
a memory card comprising a circuit board and a plurality of electronic components mounted on the circuit board;
a pair of shells sandwiching the memory card therebetween, the pair of shells covering two faces of the memory card;
a pair of clips each pushing the pair of shells toward the memory card, each of the pair of clips has a pair of abutting pieces being pivotably connected together and detachably engaged with the pair of shells.

12. The memory module assembly of claim 11, wherein the pair of clips each has a spring sandwiched between and resiliently abutting against the pair of abutting pieces thereof.

13. The memory module assembly of claim 12, the pair of clips each has two pair of tabs extending from the abutting pieces thereof and being pivotably assembled together via a post extending therethrough.

14. The memory module assembly of claim 11, wherein the abutting pieces of the pair of clips extend a plurality of protrusions detachably engaged in a plurality of indentions defined in the pair of shells.

15. The memory module assembly of claim 11, wherein one of the pair of abutting pieces of each of the pair of clips has one end thereof expanding laterally to form a board for contacting one of the pair of shells.

16. A memory module assembly comprising:
a circuit board;
a plurality of electronic components mounted on opposite faces of the circuit board;
a pair of shells mounted on the electronic components and thermally connecting therewith;
at least a clip clamping the shells toward the circuit board, the at least a clip having protrusions thereon engaging in locating depressions defined in the shells.

17. The memory module assembly of claim 16 further comprising a fastener extending through the shells and the circuit board to connect the shells and the circuit board together.

18. The memory module assembly of claim 17, wherein the fastener is located at a middle of the shells while the at least a clip is located at a side of the fastener.

19. The memory module assembly of claim 17, wherein the at least a clip has a lath with a lower portion expanding laterally to form a board contacting with a corresponding one of the shells.

20. The memory module assembly of claim 16, wherein there are two clips clamping the shells toward the circuit board, each of the two clips forms a plurality of protrusions engaging in indentions defined in the shells.
